(19) United States
(12) Patent Application Publication
(10) Pub. No.: US 2014/0127857 A1
(43) Pub. Date: May 8, 2014

(54) Carrier Wafers, Methods of Manufacture Thereof, and Packaging Methods

(71) Applicant: TAIWAN SEMICONDUCTOR MANUFACTURING COMPANY, L, Hsin-Chu (TW)

(72) Inventors: Chen-Shien Chen, Zhubei City (TW); Mirng-Ji Lii, Sinpu Township (TW); Chen-Hua Yu, Hsinchu City (TW); Yen-Chang Hu, Tai-Chung City (TW)

(73) Assignee: TAIWAN SEMICONDUCTOR MANUFACTURING COMPANY, LTD., Hsin-Chu (TW)

(21) Appl. No.: 13/671,307

(22) Filed: Nov. 7, 2012

(51) Int. Cl. B32B 7/02; H01L 21/50; C03C 27/10; B32B 17/06; C03C 27/06

(52) U.S. Cl. CPC B32B 7/02; B32B 17/06; C03C 27/06; C03C 27/10; H01L 21/50
USPC 438/107; 428/428; 428/213; 428/212; 156/60; 156/281

(57) ABSTRACT

Carrier wafers, methods of manufacture thereof, and packaging methods are disclosed. In one embodiment, a carrier wafer includes a first glass layer. The carrier wafer includes a second glass layer coupled to the first glass layer. The first glass layer has a first coefficient of thermal expansion (CTE), and the second glass layer has a second CTE.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon.

Dozens or hundreds of integrated circuits are typically manufactured on a single semiconductor wafer. The individual dies are singulated by sawing the integrated circuits along a scribe line. The individual dies are then packaged separately, in multi-chip modules, or in other types of packaging, for example.

The semiconductor industry continues to improve the integration density of various electronic components (e.g., transistors, diodes, resistors, capacitors, etc.) by continual reductions in minimum feature size, which allow more components to be integrated into a given area. These smaller electronic components also require smaller packages that utilize less area than packages of the past, in some applications.

One type of smaller packaging for semiconductor devices that has been developed is wafer level packaging (WLPs). Other recent developments in packaging for semiconductor devices include three dimensional integrated circuit (3DIC) packaging and package-on package (PoP) devices, as examples. Carrier wafers are used in some packaging process flows as a temporary mounting or support surface in the packaging process.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1 through 3 show cross-sectional views of a method of manufacturing a carrier wafer in accordance with some embodiments;

FIG. 4 is a top view of the carrier wafer shown in FIG. 3;

FIG. 5 is a cross-sectional view of a carrier wafer in accordance with other embodiments;

FIG. 6 is a chart illustrating some coefficients of thermal expansion (CTEs) of the carrier wafer and glass layers of the carrier wafer;

FIGS. 7 through 14 are cross-sectional views of a method of using the carrier wafer in accordance with some embodiments; and

FIG. 15 is a flow chart of a method of packaging a semiconductor device using the carrier wafer in accordance with some embodiments.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of some of the embodiments of the present disclosure are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

Some embodiments of the present disclosure are related to carrier wafers used to package semiconductor devices. Novel carrier wafers, methods of manufacturing thereof, and packaging methods for semiconductor devices will be described herein.

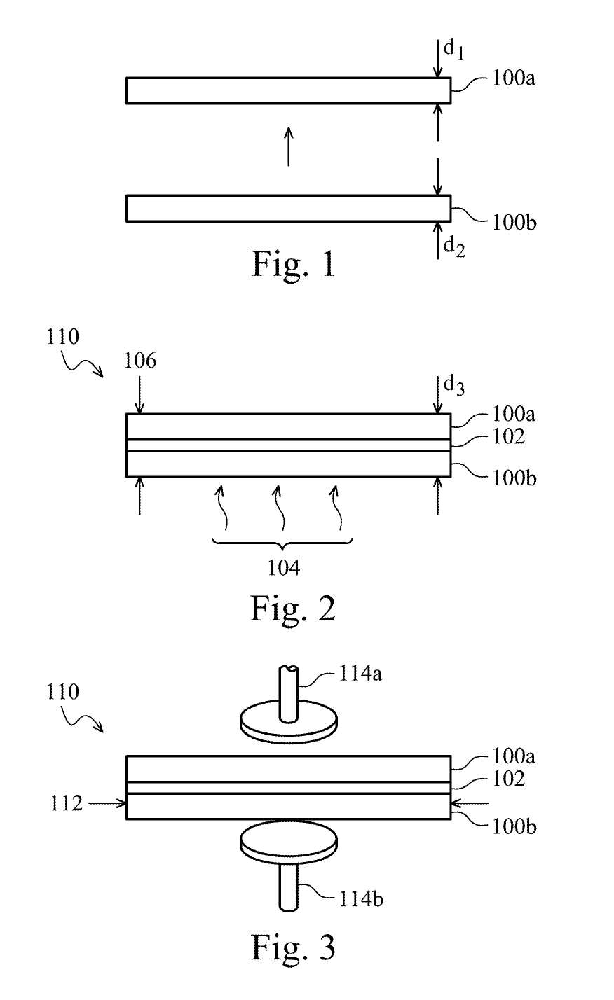

FIGS. 1 through 3 show cross-sectional views of a method of manufacturing a carrier wafer 110 (see FIG. 2) in accordance with some embodiments. Referring first to FIG. 1, there is shown a cross-sectional view of a first glass layer 100a and a second glass layer 100b being coupled to the first glass layer 100a in accordance with an embodiment of the present disclosure. The first glass layer 100a and the second glass layer 100b comprise a glass material, such as borosilicate glass, alumino-silicate glass, alkali-barium silicate glass, or quartz, as examples. The first glass layer 100a and the second glass layer 100a may comprise a primary component of SiO₂ with one or more elements included to achieve a desired characteristic for the glass in some embodiments, for example. Alternatively, the first glass layer 100a and the second glass layer 100b may comprise other materials.

The first glass layer 100a comprises a thickness comprising dimension d₁, wherein dimension d₁ is about 1.2 mm or less. The second glass layer 100a comprises a thickness comprising dimension d₂, wherein dimension d₂ is about 1.2 mm or less. In some embodiments, dimension d₂ is substantially the same as dimension d₁. In other embodiments, dimension d₂ is different than dimension d₁. Alternatively, dimensions d₁ and d₂ may comprise other values.

The first glass layer 100a comprises a first coefficient of thermal expansion (CTE), and the second glass layer 100b comprises a second CTE. The second CTE of the second glass layer 100b is different than the first CTE of the first glass layer 100a in some embodiments. The materials of the first glass layer 100a and the second glass layer 100b are selected to achieve a desired overall CTE having a predetermined value for the carrier wafer 110, in accordance with some embodiments of the present disclosure, for example, to be described further herein. The first CTE of the first glass layer 100a and the second CTE of the second glass layer 100b comprises about 5 or less or about 7 or greater in some embodiments, for example. Alternatively, the first CTE and the second CTE may comprise other values, and the second CTE may be substantially the same as the first CTE in other embodiments.

FIG. 2 is a cross-sectional view of a composite carrier wafer 110 comprising the first glass layer 100a and the second glass layer 100b. The second glass layer 100b is coupled to the first glass layer 100a using a thermal bonding process, a hydrogen bonding process, a pressure bonding process, a gluing process, and/or combinations thereof in accordance with some embodiments. For example, glue 102 may be used to bond the first and second glass layers 100a and 100b together. The glue 102 may comprise an adhesive or tape, as examples. A spin-coating may be applied to one or both of the first glass layers 100a and 100b before applying the glue 102 in some embodiments. The glue 102 may comprise a material such as benzocyclobutene (BCB) or SU-8, which may include epoxy resin, gamma butyrolactone, and triaryl sulfonium salt), as examples, although alternatively, other materials may be used. The first and second glass layers 100a and 100b may be exposed to heat 104 during the bonding process in a thermal bonding process. The first and second glass layers 100a and 100b may be heated at a temperature of about 100 degrees C. to about 250 degrees C., for example. Alternatively, other temperatures may be used. Pressure 106 may also be used to bond together the first and second glass layers 100a and 100b in a pressure bonding process. The amount of pressure 106 may comprise about 20 to 100 KN for a predetermined period of time, for example. Alternatively, other amounts of pressure 106 may be used. The pressure 106 may be applied using a clamp or other instrument or by pressure applied in a chamber, as examples. Pressure, hydrogen, and/or heat 104 may be used to bond together the first and second glass layers 100a and 100b using Van Der Vaart's force in some embodiments, for example. Alternatively, other types of bonding processes may be used.

The carrier wafer 110 comprises a total thickness comprising dimension d₃ after the bonding process, wherein dimension d₃ comprises about 1.5 mm or less in some embodiments. In some embodiments, dimension d₃ may comprise about 0.85 mm, as another example. Alternatively, dimension d₃ may comprise other values. In some embodiments, the adhesive 102 is not included in the composite carrier wafer 110.

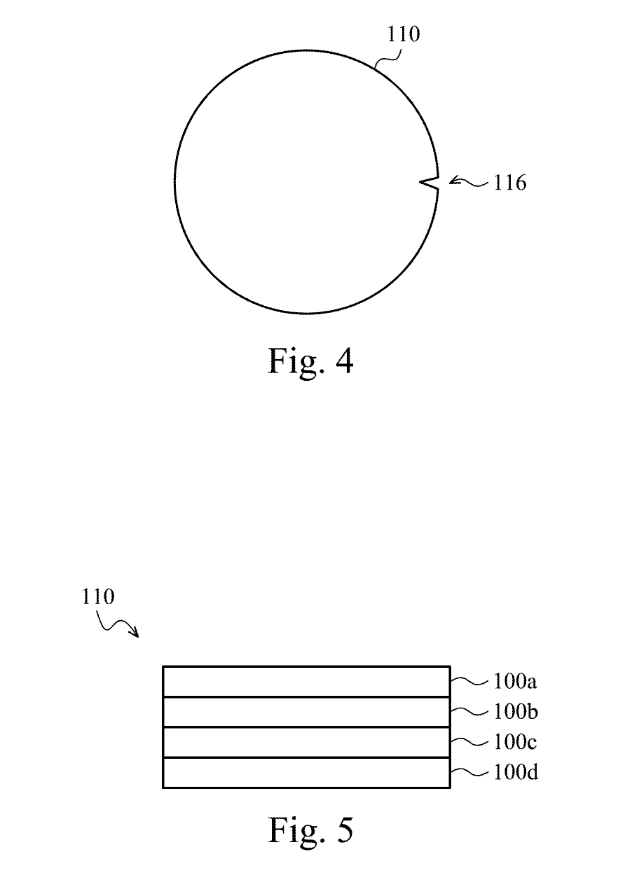

After coupling the second glass layer 100b to the first glass layer 100a, in some embodiments, the first glass layer 100a and/or the second glass layer 100b are polished using a polishing process 114a or 114b, respectively, as shown in FIG. 3. The polishing process or processes 114a and/or 114b prepare the surface or surfaces of the carrier wafer 110, for example. The carrier wafer 110 is formed using a forming process 112 in some embodiments, also illustrated in FIG. 3. The forming process 112 comprises re-shaping the edges of the first glass layer 100a and the second glass layer 100b of the carrier wafer 110 by grinding and/or smoothing the edges of the carrier wafer 110 into a predetermined desired size and shape. The shape of the carrier wafer 110 in a top view is substantially circular in some embodiments, as shown in FIG. 4.

FIG. 4 is a top view of the carrier wafer 110 shown in FIG. 3. After the bonding process, an alignment feature 116 comprising a notch or other type of alignment feature is formed on an edge of the first glass layer 100a and second glass layer 100b. A plurality of alignment features 116 may alternatively be formed on the edge of the carrier wafer 110, not shown. The carrier wafer 110 may comprise a diameter of about 300 mm in some embodiments. Alternatively, the carrier wafer 110 may comprise other sizes or dimensions.

FIG. 5 is a cross-sectional view of a carrier wafer 110 in accordance with other embodiments. The carrier wafer 110 is a composite wafer that includes a plurality of glass layers 100a, 100b, 100c, and 100d. Four glass layers 100a, 100b, 100c, and 100d are shown in FIG. 5; however, in accordance with embodiments of the present disclosure, two or more glass layers 100a, 100b, 100c, and 100d are included in the carrier wafer 100. At least one third glass layer 100c and 100d are coupled to the second glass layer 100b or the first glass layer 100a in some embodiments. Greater than four glass layers 100a, 100b, 100c, and 100d can also be included in the carrier wafer 110. The glass layers 100a, 100b, 100c, and 100d can be sequentially bonded together, or the entire stack of glass layers 100a, 100b, 100c, and 100d can simultaneously be bonded together in some embodiments, for example.

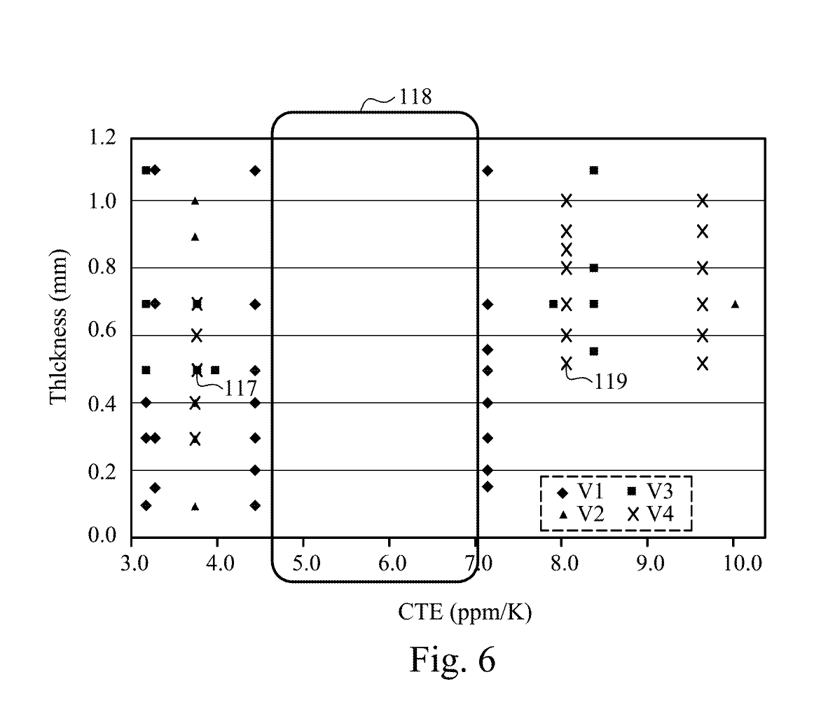

FIG. 6 is a chart illustrating some coefficients of thermal expansion (CTEs) of the carrier wafer 110 and the glass layers 100a, 100b, 100c, and 100d of the carrier wafer 110. The thickness and CTE of some currently available glass layers for commercial purchase are plotted in the chart. Plots of CTE in parts per million (ppm)/° K vs. thickness in mm of glass layers obtainable from several vendors V1, V2, V3, and V4 are shown. Region 118 illustrates a range of CTEs from between about 4.8 to 7.0 for which there are not currently glass layers available for purchase.

Advantageously, by manufacturing a composite carrier wafer 110 having a plurality of glass layers 100a and 100b as shown in FIG. 2 or glass layers 100a, 100b, 100c, and/or 100d shown in FIG. 5, a carrier wafer 110 is achievable having an overall CTE that falls within region 118 of the chart shown in FIG. 6. This is desirable in packaging applications wherein this range of CTEs is advantageous because a CTE of portions of or the entire packaging system falls within this range. Close or exact matching of the CTE to the packaging system materials is thus achievable by embodiments of the present disclosure. In some embodiments, the carrier wafer 110 comprises an overall CTE within a range of from about 3 to 11, for example. Alternatively, the overall CTE may comprise other values.

As one example, a first glass layer 100a can comprise a position 117 on the chart shown in FIG. 6 having a CTE of about 3.8, and second glass layer 100b can comprise a position 119 on the chart having a CTE of about 8.0, resulting in an overall CTE for the carrier wafer 110 of about 5.9. Various combinations of thicknesses and CTEs of the glass layers 100a, 100b, 100c, and 100d of the carrier wafer 110 can be selected to achieve a desired predetermined overall CTE value for the carrier wafer 110 that either falls within region 118, or falls below or above region 118 in CTE value, advantageously. The chart in FIG. 6 can be used to select the glass layers 100a, 100b, 100c, and 100d to achieve the desired overall CTE value for the composite carrier wafer 110 and achieve a wider process window.

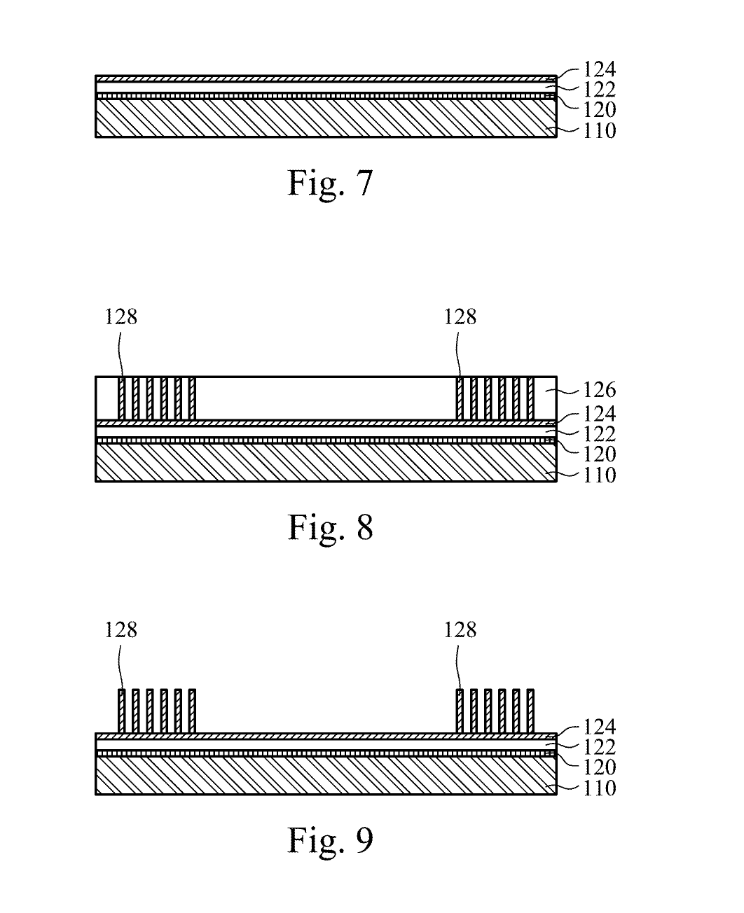

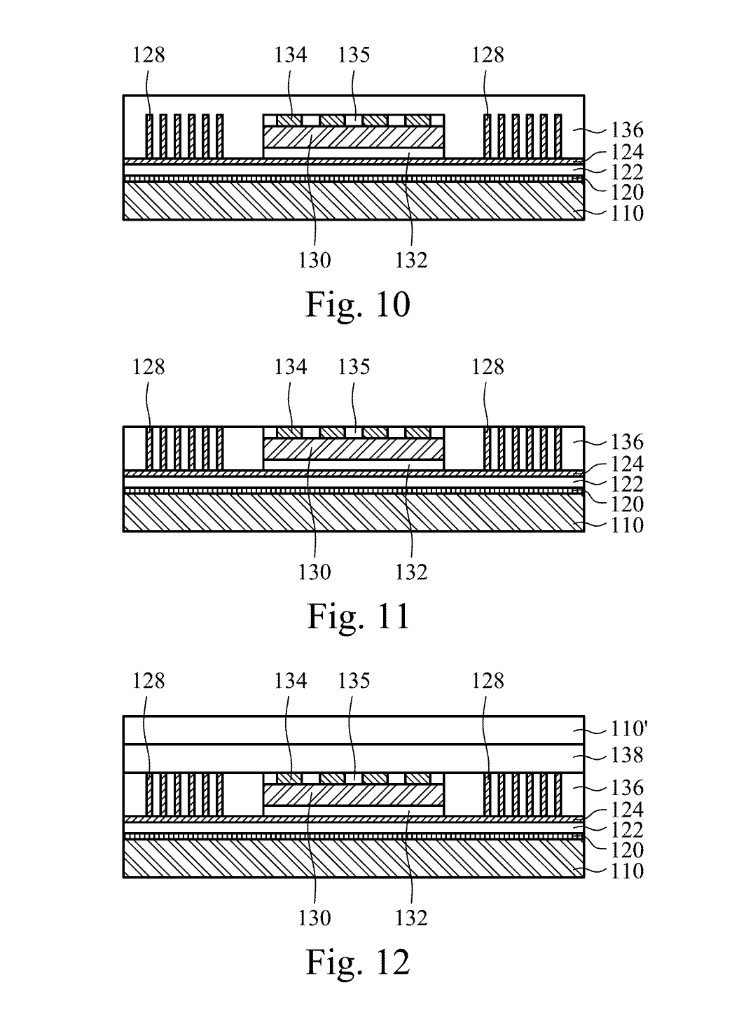

FIGS. 7 through 14 are cross-sectional views of a method of using the carrier wafers 110 described herein in accordance with some embodiments. The carrier wafers 110 are used to package semiconductor devices, such as integrated circuit dies 130 shown in FIGS. 10 through 14. Only one integrated circuit die 130 is shown in FIGS. 10 through 14; however, a plurality of integrated circuit dies 130 are packaged simultaneously over a surface of a carrier wafer 110 in accordance with some embodiments. After the carrier wafer 110 is removed, the packaged integrated circuit dies 130 are singulated into individual packaged semiconductor devices, to be described further herein.

In FIG. 7, a carrier wafer 110 described herein is first provided that includes a plurality of glass layers 100a, 100b, 100c, and/or 100d that achieve a desired CTE for the particular packaging system. The carrier wafer 110 is also referred to herein as a first carrier wafer 110. An adhesive 120 comprising glue or tape is formed over the carrier wafer 110. An insulating layer 122 comprising polybenzoxazole (PBO), polyimide, or other materials is formed over the adhesive 120. A seed layer 124 is formed over the insulating layer 122. The seed layer 124 comprises a metal that functions as a seed for a plating process for the formation of through assembly vias (TAVs) 128 (see FIG. 8).

In FIG. 8, a dry film 126 comprising an insulating material is formed over the seed layer 122. The dry film 126 is patterned using a lithography process, leaving patterns for the TAVs 128 in the dry film 126. The dry film 126 is patterned using lithography in some embodiments by depositing a layer of photoresist (not shown) over the dry film 126, and exposing the layer of photoresist to light or energy reflected from or through a lithography mask having the desired pattern formed thereon. The layer of photoresist is developed, and portions of the layer of photoresist are ashed or etched away, leaving a patterned layer of photoresist on top of the dry film 126. The layer of photoresist is then used as an etch mask while exposed portions of the dry film 126 are etched away. The layer of photoresist is then removed. The dry film 126 may also be patterned using a direct patterning process, as another example.

A plating process is used to form the TAVs 128 in the patterns in the dry film 126. The TAVs 128 comprise Cu or a Cu alloy in some embodiments. The TAVs 128 comprise a circular, oval, square, or rectangular shape in a top view in some embodiments. Alternatively, the TAVs 128 may comprise other materials and shapes. The dry film 126 is then removed, as shown in FIG. 9.

An integrated circuit die 130 is then attached to the seed layer 124 using an adhesive 132 which comprises a glue or tape, as shown in FIG. 10. The integrated circuit die 130 comprises semiconductor circuitry that is formed over a semiconductor substrate comprising silicon or other types of semiconductor materials, for example. The integrated circuit die 130 includes active components or circuits, not shown, that may comprise transistors, diodes, capacitors, inductors, and other types of devices. The integrated circuit die 130 may comprise a memory device, a logic device, or other types of circuits, as examples. The integrated circuit die 130 includes a plurality of contact pads 134 disposed within an insulating material 135 formed on a top surface thereof. The contact pads 134 comprise Cu, a Cu alloy, or other metals or materials, as examples.

A molding compound 136 is formed over the integrated circuit die 130, the TAVs 128, and exposed portions of the seed layer 124, also shown in FIG. 10. The molding compound 136 is chemically-mechanically polished to expose top surfaces of the TAVs 128 and top surfaces of the contact pads 134 of the integrated circuit die 130, as shown in FIG. 11.

A first redistribution layer (RDL) 138 is formed over the molding compound 136 and exposed top surfaces of the TAVs 128 and the contact pads 134 of the integrated circuit die 130, as shown in FIG. 12. The first RDL 138 includes one or more insulating material layers and one or more conductive line layers, not shown. The conductive line layer(s) may comprise Cu, Al, alloys thereof, or other materials, as examples. The insulating material layers may comprise silicon dioxide, silicon nitride, other insulators, or combinations thereof, as examples. The first RDL layer 138 may include fan-out regions (not shown) adapted to fan-out the footprint of the contact pads 134 of the integrated circuit die 130 to a larger footprint of the package in some embodiments, for example. In some embodiments, the first RDL 138 may include an under-ball metallization layer (UBM) on a top surface thereof for coupling a plurality of solder bumps or solder balls to, also not shown. Portions of the first RDL 138 electrically connect contact pads 134 on the integrated circuit die 130 to the TAVs 128 in some embodiments, for example.

A carrier wafer 110′ is then coupled to the first RDL 138, also shown in FIG. 12. The carrier wafer 110′ is also referred to herein as a second carrier wafer 110′. The second carrier wafer 110′ may comprise similar or different multiple glass layers 100a, 100b, 100c, and 100d described herein for the first carrier wafer 110 in some embodiments. In other embodiments, the second carrier wafer 110′ comprises a single glass layer. In yet other embodiments, the second carrier wafer 110′ comprises multiple glass layers 100a, 100b, 100c, and 100d, and the first carrier wafer 110 comprises a single glass layer. At least one of the first carrier wafer 110 and the second carrier wafer 110′ comprises multiple glass layers 100a, 100b, 100c, and 100d in accordance with some embodiments of the present disclosure.

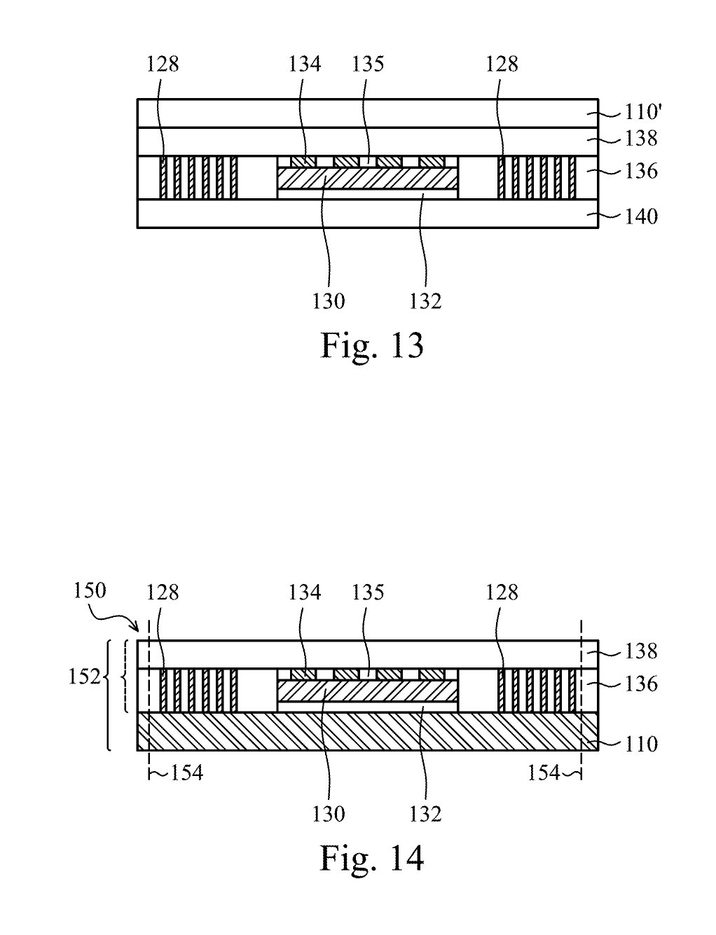

After the second carrier wafer 110′ is attached to the first RDL 138, the first carrier wafer 110 is removed using a de-bonding process, as shown in FIG. 13. The adhesive 120, the insulating layer 122, and the seed layer 124 are also removed using one or more etch processes or de-bonding processes. A second RDL 140 is then formed on the bottom surface of the molding compound 136, the exposed bottom surfaces of the TSVs 128, and over the bottom surface of the integrated circuit die 130. The second RDL 140 may comprise similar material layers as described for the first RDL 138, for example. The second carrier wafer 110′ is then removed using a de-bonding process, as shown in FIG. 14.

A packaged semiconductor device 150 is shown that includes a packaging system 152 and the integrated circuit die 130. In some embodiments, the packaging system 152 formed over the integrated circuit die 130 includes both a first RDL 138 and a second RDL 140. In other embodiments, the packaging system 152 includes only the first RDL 138, as shown in phantom in FIG. 14. The packaging system 152 includes the elements shown in FIG. 14 except for the integrated circuit die 130; i.e., the integrated circuit die 130 is packaged using the packaging system 152. The TAVs 128 provide vertical connections for the packaging system 152, e.g., between the first and second RDLs 138 and 140. The first and second RDLs 138 and 140 provide horizontal connections for the packaging system 152 in some embodiments.

After the process flow shown in FIGS. 7 through 14, the packaged integrated circuit dies 130 comprising packaged semiconductor devices 150 are singulated along scribe lines 154, as shown in FIG. 14. The packaging systems disposed over the integrated circuit dies 130 are singulated at the scribe lines 154 to form a plurality of individual packaged semiconductor devices 150, for example. Each packaged semiconductor device 150 can be coupled to another packaged semiconductor device 150 by coupling a plurality of solder bumps or solder balls to the first RDL 138 and/or the second RDL 140. The solder bumps or balls can then be coupled to an RDL 138 or 140 of another packaged semiconductor device 150 described herein, or to another type of packaged semiconductor device, to form a package-on-package (PoP) device (not shown).

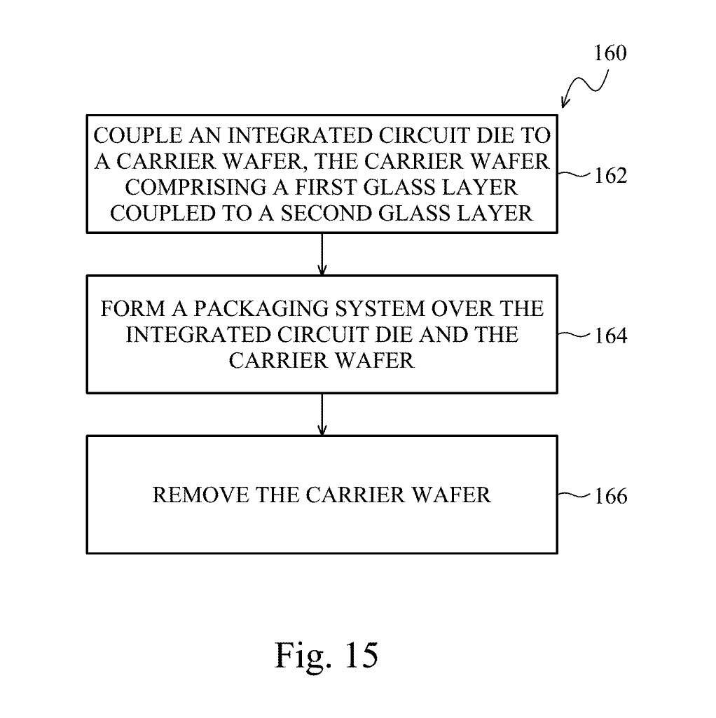

FIG. 15 is a flow chart 160 of a method of packaging a semiconductor device in accordance with some embodiments. In step 162, an integrated circuit die 130 is coupled to a carrier wafer 110, the carrier wafer 110 comprising a first glass layer 100a coupled to a second glass layer 100b (see also FIG. 10). In step 164, a packaging system 152 is formed over the integrated circuit die and the carrier wafer 110 (FIG. 14). In step 166, the carrier wafer 110 is removed (FIGS. 12 and 13).

Some embodiments of the present disclosure include methods of forming composite carrier wafers 110 having multiple glass layers 100a, 100b, 100c, and/or 100d, and also include carrier wafers 110 that include the multiple glass layers 100a, 100b, 100c, and 100d. Some embodiments of the present disclosure include methods of packaging semiconductor devices using the novel carrier wafers 110.

Advantages of some embodiments of the disclosure include providing novel composite carrier wafers 110 that include multiple glass layers 100a, 100b, 100c, and/or 100d. Carrier wafers 110 that have a substantially equivalent CTE to CTE values of a variety of packaging systems and structures are achievable by some embodiments described herein. Flexible CTE values are achievable by including the plurality of glass layers 100a, 100b, 100c, and 100d in the carrier wafer 110 structure. The ability to match the CTE to the CTE of the packaging system results in warpage reduction, warpage optimization, and warpage control for the packaged semiconductor devices 150, and also results in a wider bumping process margin, e.g., of solder bumps subsequently formed on the first RDL 138 or the second RDL 140. Overall CTE ranges for the carrier wafers 110 are achievable that reside within CTE ranges that are not currently commercially available in single layer carrier wafers, advantageously. The novel carrier wafer 110 structures and designs are easily implementable in packaging process flows.

In accordance with some embodiments of the present disclosure, a carrier wafer includes a first glass layer and a second glass layer coupled to the first glass layer. The first glass layer comprises a first CTE, and the second glass layer comprises a second CTE.

In accordance with other embodiments, a method of manufacturing a carrier wafer includes providing a first glass layer, and coupling a second glass layer to the first glass layer. The first glass layer comprises a first CTE, and the second glass layer comprises a second CTE.

In accordance with other embodiments, a method of packaging a semiconductor device includes providing a carrier wafer including a first glass layer coupled to a second glass layer. The method includes coupling a plurality of integrated circuit dies over the carrier wafer, forming a packaging system over each of the plurality of integrated circuit dies and the carrier wafer, and removing the carrier wafer.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A carrier wafer, comprising:
a first glass layer; and
a second glass layer coupled to the first glass layer, wherein the first glass layer comprises a first coefficient of thermal expansion (CTE), and wherein the second glass layer comprises a second CTE;
wherein the first and second glass layers are free of metallization, configured to temporarily support a wafer, and to be removed from the wafer at a bonding surface between the wafer and one of the first and second glass layers thereafter.

2. The carrier wafer according to claim 1, wherein the first glass layer comprises a first thickness, and wherein the second glass layer comprises a second thickness.

3. The carrier wafer according to claim 2, wherein the second thickness is substantially the same as the first thickness.

4. The carrier wafer according to claim 2, wherein the second thickness is different than the first thickness.

5. The carrier wafer according to claim 1, wherein the second CTE is different than the first CTE.

6. The carrier wafer according to claim 1, wherein the second CTE is substantially the same as the first CTE.

7. The carrier wafer according to claim 1, wherein the carrier wafer comprises an overall CTE within a range of about 3 to 11.

8. The carrier wafer according to claim 1, wherein the first CTE or the second CTE comprises about 5 or less or about 7 or greater.

9. A method of manufacturing a carrier wafer, the method comprising:
providing a first glass layer, the first glass layer comprising a first coefficient of thermal expansion (CTE);
coupling a second glass layer to the first glass layer, wherein the second glass layer comprises a second CTE and wherein the first and second glass layers are free of metallization, configured to temporarily support a wafer, and to be removed from the wafer at a bonding surface between the wafer and one of the first and second glass layers thereafter.

10. The method according to claim 9, further comprising coupling at least one third glass layer to the second glass layer or the first glass layer.

11. The method according to claim 9, wherein coupling the second glass layer to the first glass layer comprises using a process selected from the group consisting essentially of a thermal bonding process, a hydrogen bonding process, a pressure bonding process, a gluing process, and combinations thereof.

12. The method according to claim 9, further comprising polishing the first glass layer or the second glass layer, after coupling the second glass layer to the first glass layer.

13. The method according to claim 9, further comprising forming the first glass layer and the second glass layer into a predetermined shape.

14. The method according to claim 9, further comprising forming an alignment feature on an edge of the first glass layer and the second glass layer.

15. The method according to claim 9, further comprising selecting the first glass layer having the first CTE and selecting the second glass layer having the second CTE to achieve an overall CTE for the carrier wafer of a predetermined value.

16-20. (canceled)
